(19) United States
(12) Patent Application Publication
(10) Pub. No.: US 2007/0205426 A1
(43) Pub. Date: Sep. 6, 2007

(54) Semiconductor light-emitting device

(75) Inventors: Kyoji Inoshita, Hirakata-city (JP); Yasumitsu Kunoh, Hirakata-city (JP); Saburo Nakashima, Yawata-city (JP); Tatsuya Kunisato, Takatsuki-city (JP); Takenori Goto, Moriguchi-city (JP); Masayuki Hata, Kadoma-city (JP)

Correspondence Address: NDQ&M WATCHSTONE LLP, 1300 EYE STREET, NW, SUITE 1000 WEST TOWER, WASHINGTON, DC, 20005, US

(73) Assignee: Sanyo Electronic Co., Ltd., Moriguchi (JP)

(21) Appl. No.: 11/699,495

(22) Filed: Jan. 30, 2007

(30) Foreign Application Priority Data
Jan. 31, 2006 (JP) P2006-023349
Dec. 28, 2006 (JP) P2006-356569

(51) Int. Cl. H01L 33/00

(52) U.S. Cl. 257/99

(57) ABSTRACT

A semiconductor light-emitting device includes a semiconductor light-emitting element and a lead-out electrode. The semiconductor light-emitting element has a light-emitting surface of polygonal shape and an electrode formed on the light-emitting surface. The lead-out electrode is connected to the electrode. In the semiconductor light-emitting device, the electrode is formed along at least two sides of the light-emitting surface. In addition, the lead-out electrode is formed on the electrode, and includes an opening portion which opens toward an upper side of the light-emitting surface.

### CROSS-REFERENCE TO RELATED APPLICATIONS

This application is based upon and claims the benefit of priority from prior Japanese Patent Application No. 2006-23349, filed on January 31; and prior Japanese Patent Application No. 2006-356569, filed on December 28; the entire contents of which are incorporated herein by reference.

### BACKGROUND OF THE INVENTION

1. Field of the Invention

The present invention relates to a semiconductor light-emitting device including a semiconductor light-emitting element capable of emitting light.

2. Description of the Related Art

Heretofore, a semiconductor light-emitting device including a semiconductor light-emitting element (a light-emitting diode) capable of emitting light has been known. The semiconductor light-emitting element has advantages including compactness, low power consumption, and long service life. In addition, the semiconductor light-emitting element is capable of emitting light in a wide range of wavelength, from an infrared light to an ultraviolet light including visible light. For this reason, a semiconductor light-emitting device including the semiconductor light-emitting element is used as a substitute for existing light-emitting devices including a small electric lamp, or is used in a display device.

As such a semiconductor light-emitting device, the following one is known. In the semiconductor light-emitting device, an electrode is provided to the top surface of a semiconductor light-emitting element, from which surface a large portion of light emits, and the electrode is wire-bonded to an outside electrode.

However, there are the following problems with such a semiconductor light-emitting element in which an electrode is wire-bonded to an outside electrode.

First, there is a problem that heat radiation from the upper surface of the semiconductor light-emitting element is low. In a general semiconductor light-emitting element, heat is radiated from the bottom surface thereof to a heat sink or the like through a plate or thin film electrode. However, from the top surface of the semiconductor light-emitting element, heat is radiated only through a thin wire having a small cross sectional area, or through resin or the like having a poor thermal conductivity. For this reason, the heat radiation of the semiconductor light-emitting element is very low. In particular, the following problem occurs when a large current is caused to flow through the semiconductor light-emitting element for operating the semiconductor light-emitting diode with high output power. When a large current flows through the semiconductor light-emitting element, the temperature of the semiconductor light-emitting element becomes considerably high due to a low heat radiation. As a result, the semiconductor light-emitting device is deteriorated.

Furthermore, there is another problem since a wire for connecting the electrode to another has a small cross sectional area. When a large current flows through the wire, the wire is easily damaged since the wire is burnt by heat. For this reason, a large current cannot be caused to flow through the semiconductor light-emitting element. In the meantime, in Japanese Patent Publication Nos. 2004-265986 and 2005-5437, proposed is the following technique. Multiple electrodes are formed on the top surface of a semiconductor light-emitting element, Then, the electrodes are bonded to an outside electrode by use of multiple wires. Thereby, current is dispersed. However, another problem occurs here. The surface areas of electrodes need to be larger than those of wires. Accordingly, when the multiple electrodes not emitting light are formed on the top surface-of the semiconductor light-emitting element, the light extraction efficiency thereof is reduced.

Furthermore, when connecting electrodes by wire bonding, current is supplied to the semiconductor light-emitting diode through only regions where the electrodes are connected by the wires. Accordingly, carrier diffusion becomes insufficient. For this reason, a problem arises that light is not evenly emitted from a light-emitting layer of the semiconductor since carriers are supplied to only partial regions of the light-emitting layer of the semiconductor light-emitting element. Especially, in the case of a thin type element, in which a thickness of a semiconductor layer above a light-emitting layer is only several μm, carrier diffusion becomes insufficient, and non-uniformity of light emission from the light-emitting region is pronounced.

Here, in Japanese Patent Publication No. 2003-168762, disclosed is a technique using the following structure. In this structure, a lead-out electrode of plate shape is connected to an electrode formed on a surface from which light of the semiconductor light-emitting element emits in a way that the electrode covers one side of the surface. By adapting such a structure, the heat radiation is improved to some extent by having the lead-out electrode of plate shape. At the same time, by forming the cross sectional area of the electrode larger than that of a wire, the wire can be prevented from being burnt and then from being cut by heat generated in the lead-out electrode.

In the technique disclosed in Japanese Patent Publication No. 2003-168762, since the electrode is formed in a way to cover one side of the surface from which light of the semiconductor light-emitting element emits, carriers can be dispersed to some extent in comparison with a case of using wire-bonding, where carriers are supplied from a single point. However, it is hard to say that carriers are dispersed evenly enough. Especially, a large amount of carriers are not injected in a region of a light-emitting layer corresponding to a side facing to the side where the electrode is formed. For this reason, only weak light is emitted from the region of the light-emitting layer. Consequently, there is a problem that light is emitted non-uniformly from the semiconductor light-emitting element disclosed in Japanese Publication No. 2003-168762.

Furthermore, in Japanese Patent Publication No. 2003-168762, since the electrode is formed on only one side of the surface, it is hard to say that the heat radiation of the semiconductor light-emitting diode is sufficiently improved, and that the electrode is sufficiently prevented from being damaged due to large-current.

### SUMMARY OF THE INVENTION

In a first aspect of the present invention, a semiconductor light-emitting device includes a semiconductor light-emitting element and an electrode. The semiconductor light-emitting element has a light-emitting surface of polygonal shape. The electrode is formed on the light-emitting surface. The electrode is formed along at least two sides of the light-emitting surface. The lead-out electrode is formed on the electrode, and includes an opening portion which opens toward an upper side of the light-emitting surface.

According to the first aspect of the invention, since the electrode is formed along at least two sides of the light-emitting surface, it is possible to evenly diffuse carriers into the semiconductor light-emitting element while pursuing expansion of the region from which the carriers are supplied to the semiconductor light-emitting element. It should be noted that the light-emitting surface is a surface from which a major portion of light emits.

Moreover, since the lead-out electrode which at least covers the electrode includes an opening portion provided with an opening on an upper side of the light-emitting surface of the semiconductor light-emitting element, it is possible to control light emitted from the light-emitting surface so as not to be hindered by the lead-out electrode.

Furthermore, since the electrode is formed along at least two sides of the light-emitting surface while being covered by the lead-out electrode, a region from which heat is to be radiated from the semiconductor light-emitting element increases. This makes it possible to pursue improvement in heat radiation. Moreover, current flowing the lead-out electrode is diffused, even in a case where large current is caused to flow through the lead-out electrode. Accordingly, it is possible to prevent the lead-out electrode from being damaged by being burnt and then being cut due to heat. Thereby, it is made possible to supply large current to the semiconductor light-emitting element, and thus to increase an amount of light to be emitted from the semiconductor light-emitting element.

In a second aspect of the invention, in addition to the aspect described above, the semiconductor light-emitting element emits any one of a blue light or an ultraviolet light from the light-emitting surface. Moreover, the semiconductor light-emitting device further includes a phosphor, which emits a fluorescent light by absorbing the light emitted from the light-emitting surface as an excitation light. The phosphor is provided to an area of the light-emitting surface, on which the electrode is not formed.

In a third aspect of the invention, in addition to the aspect described above, the lead-out electrode includes an auxiliary opening portion which opens toward the upper side of the semiconductor light-emitting device. The auxiliary opening portion is provided to an outside of the opening portion.

In a fourth aspect of the invention, in addition to the aspect described above, the lead-out electrode includes an inner frame in the opening portion. The electrode is disposed along the inner frame, and disposed on the light-emitting surface.

In fifth aspect of the invention, in addition to the aspect described above, a bottom surface of the lead-out electrode, side surfaces of the semiconductor light-emitting element, and side surfaces of the electrode, are filled with an insulating material.

In a sixth aspect of the invention, in addition to the aspect described above, the semiconductor light-emitting element is provided on a substrate made of a non-light-transparent material.

### BRIEF DESCRIPTION OF THE DRAWINGS

FIG. 1 is a view showing a cross sectional structure of a semiconductor light-emitting device of a first embodiment according to the present invention.

FIG. 2 is a plan view of the semiconductor light-emitting device of the first embodiment according to the present invention.

FIG. 3 is a plan view of the semiconductor light-emitting device, from which an n-side lead-out electrode and so on are removed, of the first embodiment according to the present invention.

FIG. 4 is a view showing a cross sectional structure of a semiconductor light-emitting device of a second embodiment according to the present invention.

FIG. 5 is a view showing a cross sectional structure of a semiconductor light-emitting device of a third embodiment according to the present invention.

FIG. 6 is a view showing a cross sectional structure of a semiconductor light-emitting device of a fourth embodiment according to the present invention.

FIGS. 7A and 7B are views each showing an assembly process of the semiconductor light-emitting device of a fourth embodiment according to the present invention.

FIG. 8 is a view showing a cross sectional structure of a semiconductor light-emitting device of a fifth embodiment according to the present invention.

FIG. 9 is a plan view of the semiconductor light-emitting device of the fifth embodiment according to the present invention.

FIGS. 10A and 10B are plan views respectively showing modified examples of the semiconductor light-emitting device of the fifth embodiment according to the present invention.

FIG. 11 is a plan view showing a semiconductor light-emitting device of a modified embodiment according to the present invention.

### DESCRIPTION OF THE PREFERRED EMBODIMENTS

### First Embodiment

(Structure of Semiconductor Light-Emitting Device)

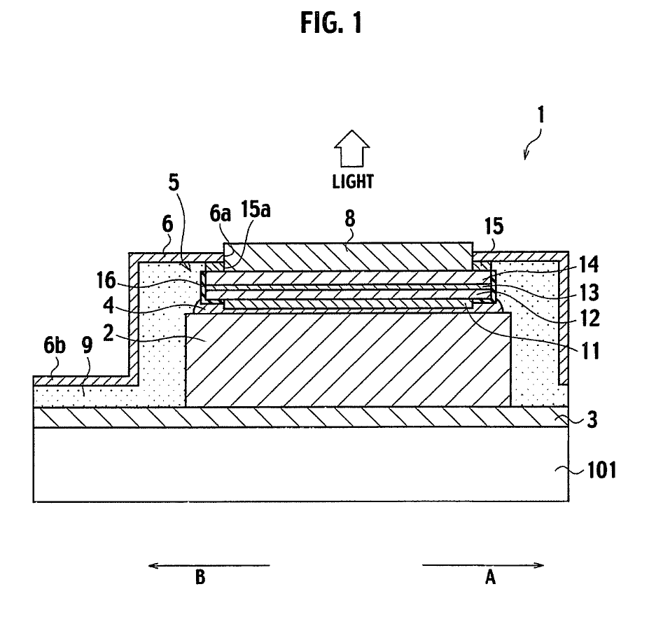

Hereinafter, a first embodiment where the present invention is applied to a semiconductor light-emitting device of a surface mount type will be described with reference to FIGS. 1 to 3.

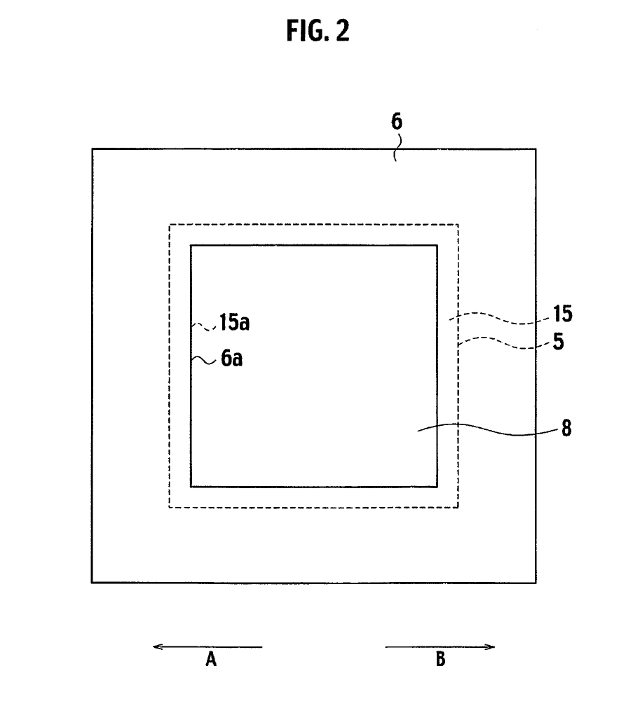

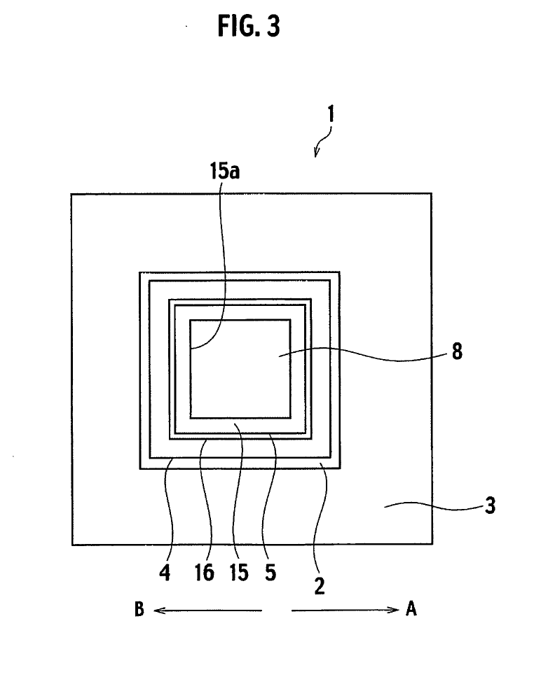

FIG. 1 is a view showing a cross sectional structure of a semiconductor light-emitting device of the first embodiment according to the present invention. FIG. 2 is a plan view of the semiconductor light-emitting device of the first embodiment according to the present invention. FIG. 3 is a plan view of the semiconductor light-emitting device from which an n-side lead-out electrode and so on are removed, the semiconductor light-emitting device being of the first embodiment according to the present invention.

As shown in FIGS. 1 to 3, a semiconductor light-emitting device 1 includes a base plate 101, a conductive layer 3 provided on the base plate 101, a supporting substrate 2 provided on the conductive layer 3, a bonding layer 4, a semiconductor light-emitting element 6 (a light-emitting diode), an n-side lead-out electrode 6 (which corresponds to a lead-out electrode in claims), a phosphor sheet 8 (which corresponds to a phosphor in claims), and a resin layer 9.

The supporting substrate 2 is made of a conductive material being non-transparent of light emitted by the semiconductor light-emitting element 5, and having a high thermal conductivity.

The semiconductor light-emitting element 5 is a GaN light-emitting diode capable of emitting blue light or ultraviolet light. After being formed on a growth substrate, the semiconductor light-emitting element 5 is replaced onto the supporting substrate 2. Specifically, the semiconductor light-emitting element 5 is removed from the growth substrate, after being attached onto the supporting substrate 2 by fusion bonding with the bonding layer 4. Here, the semiconductor light-emitting element 5 is of a thin type, and the area of the top surface of the semiconductor light-emitting element 5 is larger than that of a side surface thereof, so that an amount of light emitted from the top surface is greater than from the side surface. Accordingly, by replacing the semiconductor light-emitting element 5 onto the supporting substrate 2, light emitted therefrom can be reflected by the conductive layer 3, the bonding layer 4 or the supporting substrate 2. Thus, by controlling light emitted from the side surface of the semiconductor light-emitting element 5, a larger amount of light can emit upwards. Furthermore, as shown in FIG. 3, the top surface (the surface from which light emits) of the semiconductor light-emitting element 5 is formed in a quadrangular shape when viewed in a plan view.

As shown in FIG. 1, in the semiconductor light-emitting element 5, a p-side electrode 11, a p-type semiconductor layer 12, a light-emitting layer 13, an n-type semiconductor layer 14, and an n-side electrode 15 (which corresponds to an electrode in claims) are sequentially laminated from the supporting substrate 2. Moreover, side surfaces of the semiconductor light-emitting element 5 are covered by an insulating layer 16. As shown in FIG. 3, the n-side electrode 15 is formed into a quadrangular shape along four sides of the top surface of the semiconductor light-emitting element 5 of a rectangular shape. As shown in FIG. 3, a light-emitting window 15a is formed at the inner side of the n-side electrode 15 so as to expose the top surface of the n-type semiconductor layer 14 of the semiconductor light-emitting element 5. It should be noted that the semiconductor light-emitting element 5 including the n-side electrode 15 is fabricated by use of a publicly known semiconductor manufacturing method such as a CVD method or an etching method.

The n-side lead-out electrode 6 is formed of a metallic plate material having a good thermal conductivity, such as Au or Al. As shown in FIG. 1, the n-side lead-out electrode 6 is fixed by the resin layer 9 and mounted on an upper portion of the semiconductor light-emitting element 5, and is provided in a way that the n-side lead-out electrode 6 covers the supporting substrate 2. As shown in FIG. 2, an opening portion 6a (which corresponds to an opening portion in claims) having an opening of the same shape as that of the light-emitting window 15a is provided to a portion of the n-side lead-out electrode 6, which portion corresponds to the light-emitting window 15a of the n-side electrode 15. A portion of an outer frame of the opening portion 6a and the n-side electrode 15 are connected with each other by thermocompression bonding or by use of conductive adhesive. Part of the n-side lead-out electrode 6 is bent towards a lower part of the semiconductor light-emitting element 5 in a direction indicated by an arrow B in FIG. 2. An end part, in the direction B, of the lead-out electrode 6 are bent outward in a horizontal direction, and forms an n-side terminal 6b, which is to be connected to an outside electrode by a lead line or the like.

The phosphor sheet 8 is a phosphor including a fluorescent material which absorbs blue light or ultraviolet light emitted by the semiconductor light-emitting element 5 as an excitation light, and which then emits white light. The phosphor sheet 8 is provided to the opening portion 6a and the light-emitting window 15a where the n-side lead-out electrode 6 and the n-side electrode 15 are not formed. The resin layer 9 is formed in a way that the resin layer 9 is buried between the n-side lead-out electrode 6, the supporting substrate 2 and the conductive layer 3. Here, the resin layer 9 is filled in the space formed by the bottom surface of the n-side lead-out electrode 6, the side surfaces of the semiconductor light-emitting element 5, and the top surface of the conductive layer 3. Accordingly, the resin layer 9 prevents a short-circuit between the n-side lead-out electrode 6 and the conductive layer 3 by securing electrical isolation between the n-side lead-out electrode 6 and the conductive layer 3. Moreover, the resin layer 9 also fixes the n-side lead-out electrode 6 and the conductive layer 3 to each other while being interposed therebetween. Accordingly, even when a force or impact is applied to the semiconductor light-emitting device 1, it is possible to maintain electrical isolation between the n-side lead-out electrode 6 and the conductive layer 3. Incidentally, in order to protect the semiconductor light-emitting device 1, another resin layer may be provided so as to entirely cover the semiconductor light-emitting device 1.

In this semiconductor light-emitting device 1, when a voltage is applied between the conductive layer 3 and the n-side lead-out electrode 6, holes are injected into the semiconductor light-emitting element 5 from the conductive layer 3 through the supporting substrate 2, the bonding layer 4, and the p-side electrode 11. At the same time, electrons are injected into the semiconductor light-emitting element 5 from part of the bottom surface of the n-side lead-out electrode 6 through the n-side electrode 15 formed surrounding part of the top surface of the semiconductor light-emitting element 5. The holes and electrons injected into the semiconductor light-emitting element 5 are injected into the light-emitting layer 13 through the p-type semiconductor layer 12 and the n-type semiconductor layer 14, respectively. Then the holes and electrons are recombined to cause light emission. The emitted light emits upwards through the light-emitting window 15a of the n-side electrode 15 and the opening portion 6a of the n-side lead-out electrode 6.

(Function and Effects)

As described above, in the semiconductor light-emitting device 1 of the first embodiment according to the present invention, the n-side electrode 15 is formed along the four side of the top surface of the semiconductor light-emitting element 5. Concurrently, in the semiconductor light-emitting device 1, the n-side lead-out electrode 6 is connected to the n-side electrode 15 in a way that the n-side lead-out electrode 6 covers the n-side electrode 15. This allows electrons to be injected from four sides of the top surface of the semiconductor light-emitting element 5. Thereby, the electrons to be injected into the semiconductor light-emitting element 5 through the n-side electrode 15 can be sufficiently diffused in the surface direction of the light-emitting layer 13. Accordingly, the electrons and holes can be recombined in the overall region of the light-emitting layer 13, thereby light can be emitted from the entire surface of the light-emitting layer 13.

In the semiconductor light-emitting device 1, the n-side electrode 15 is formed in a portion corresponding to the four sides of the top face of the semiconductor light-emitting element 5. Accordingly, it is possible to efficiently radiate, to the outside, heat generated by light emission from the semiconductor light-emitting element 5. Furthermore, the semiconductor light-emitting device 1 can radiate a large amount of heat to the outside since the n-side lead-out electrode 6 is formed in a way that the n-side lead-out electrode 6 covers the supporting substrate 2.

In the semiconductor light-emitting device 1, the n-side electrode 15 is formed along the four sides of the top surface of the semiconductor light-emitting element 5. Moreover, in the semiconductor light-emitting device 1, the n-side lead-out electrode 6 is formed in a way that the n-side lead-out electrode 6 covers the n-side electrode 15. Accordingly, it is possible to increase the cross sectional area of the n-side lead-out electrode 6 in comparison with a case where bonding wire is employed. For this reason, even when a large current is caused to flow through the n-side lead-out electrode 6, the n-side lead-out electrode 6 can be prevented from being damaged since the current is diffused, and electrical resistance of the n-side lead-out electrode 6 is reduced. Accordingly, it is possible to flow a large current through the semiconductor light-emitting element 5 and to thus realize light emission with high output power.

In the semiconductor light-emitting device 1, the opening portion 6a is formed on the n-side lead-out electrode 6 and the light-emitting window 15a is formed on the n-side electrode 15. For this reason, light emitted from the semiconductor light-emitting element 5 can be prevented from being hindered by the n-side lead-out electrode 6 or the n-side electrode 15, Accordingly, the efficiency in extracting light emitted from the semiconductor light-emitting element 5 can be improved. Moreover, in the semiconductor light-emitting device 1, light proceeding downward can be prevented from emitting therethrough by providing, to the semiconductor light-emitting device 1, the supporting substrate 2, the bonding layer 4, and the conductive layer 3, which do not allow the light to emit through themselves. Accordingly, a larger amount of light can emit upwards. Furthermore, the semiconductor light-emitting device 1 can emit white light by being provided with the semiconductor light-emitting element 5 capable of emitting blue light or ultraviolet light and the phosphor sheet 8.

### Second Embodiment

(Structure of Semiconductor Light-Emitting Device)

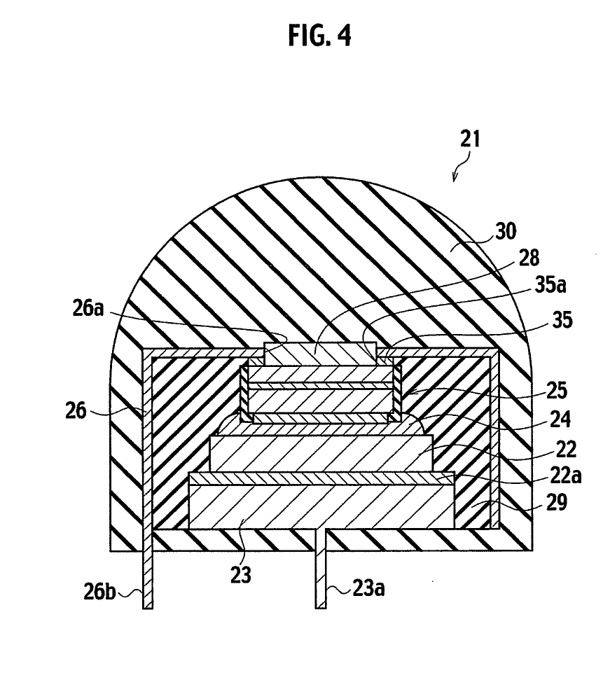

Next, a second embodiment in which the present invention is applied to a semiconductor light-emitting device of a lamp type will be described with reference to FIG. 4.

FIG. 4 is a view showing a cross sectional structure of a semiconductor light-emitting device of the second embodiment according to the present invention.

As shown in FIGS. 4, a semiconductor light-emitting device 21 includes a supporting substrate 22, a p-side lead-out electrode 23, a bonding layer 24, a semiconductor light-emitting element 25, an n-side lead-out electrode 26, a phosphor sheet 28, a resin layer 29, and a molded resin portion 30.

Descriptions of the supporting substrate 22, the bonding layer 24, the semiconductor light-emitting element 25, the phosphor sheet 28, and the resin layer 29, are omitted here, since the configurations of these elements are the same as those of the supporting substrate 2, the bonding layer 4, the semiconductor light-emitting element 5, the phosphor sheet 8, and the resin layer 9, respectively. Furthermore, as in the case of the n-side electrode 15 of the semiconductor light-emitting element 5 of the first embodiment, an n-side electrode 35 provided on the top surface of the semiconductor light-emitting element 25 is formed along the four sides of the top surface of the semiconductor light-emitting element 25, and a light-emitting window 35a of a quadrangular shape is formed at the inner side of the n-side electrode 35. It should be noted that, as shown in FIG. 4, the supporting substrate 22 and the semiconductor light-emitting element 25 are connected with each other with only the bonding layer 24 interposed therebetween. Moreover, a concave portion may be formed on the supporting substrate 22 for disposing the semiconductor light-emitting element 25.

The p-side lead-out electrode 23 is formed on the bottom surface of a conductive layer 22a provided under the bottom surface of the supporting substrate 22. The p-side lead-out electrode 23 is connected to the semiconductor light-emitting element 25 through a p-side terminal 23a, the conductive layer 22a, and the supporting substrate 22, and the bonding layer 24. The p-side terminal 23a, which is to be connected to an outside electrode, is formed at a lower end portion of the p-side lead-out electrode 23.

Both end portions of the n-side lead-out electrode 26 are bent downward to increase a surface area thereof so that heat radiation can be increased. Furthermore, one of the end portions of the n-side lead-out electrode 26 is formed longer than the other end portion. Then, an n-side terminal 26b is formed at the longer end portion. Moreover, the n-side lead-out electrode 26 is provided in a way that the top surface of the n-side lead-out electrode 26 covers the n-side electrode 35. Furthermore, an opening portion 26a of the same rectangular shape as that of the light-emitting window 35a is formed on a portion of the top surface of the lead-out electrode 26, which corresponds to the light-emitting window 35a of the n-side electrode 35.

(Function and Effects)

As described above, the semiconductor light-emitting device 21 of a lamp type of the second embodiment includes the n-side electrode 35 and the n-side lead-out electrode 26. The n-side electrode 35 is formed along the four sides of the top surface of the semiconductor light-emitting element 25, and the light-emitting window 35a is formed therein. The n-side lead-out electrode 26 is formed in a way that the n-side lead-out electrode 26 covers the n-side electrode 35, and the opening portion 26a corresponding to the light-emitting window 35a is formed therein. Accordingly, the semiconductor light-emitting device 21 of a lamp type of the second embodiment can obtain the same effects as those of the first embodiment.

### Third Embodiment

(Structure of Semiconductor Light-Emitting Device)

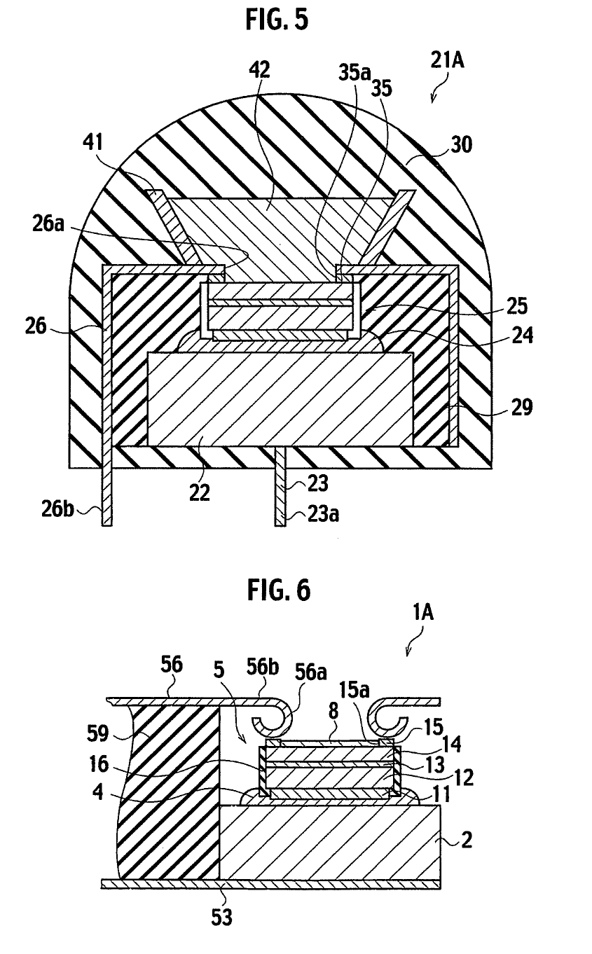

Next, a third embodiment will be explained with reference to FIG. 5. The third embodiment is an embodiment in which partial modification is applied to the second embodiment.

FIG. 5 is a view showing a cross sectional structure of a semiconductor light-emitting device of a third embodiment according to the present invention. It should be noted that same reference numerals are assigned to the elements which are the same as those of the second embodiment, and thus, descriptions thereof will be omitted here.

As shown in FIG. 5, a semiconductor light-emitting device 21A is provided with a phosphor cap 41. The phosphor cap 41 is provided in a way that the phosphor cap 41 surrounds the outer sides of an opening portion 26a which is formed on an n-side lead-out electrode 26. The phosphor cap 41 is formed in a shape of a partial quadrangular pyramid having the top surface area larger than the bottom surface area. A cavity is formed inside the phosphor cap 41, and a phosphor 42 made of resin including multiple types of fluorescent materials is filled therein. It should be noted that the phosphor 42 is prepared in a manner that liquid resin including the fluorescent materials is injected in the phosphor cap 41, and thereafter, the injected liquid resin is cured by heating.

In the semiconductor light-emitting device 21A of the third embodiment, the phosphor cap 41 of a shape of a partially quadrangular pyramid is provided on the top surface of the n-side lead-out electrode 26. For this reason, the phosphor 42 of resin form can be easily retained in the phosphor cap 41 when preparing the phosphor 42. Accordingly, the fabrication process of the phosphor 42 can be simplified. In addition, the same effects as those of the first embodiment can be obtained.

### Fourth Embodiment

(Structure of Semiconductor Light-Emitting Device)

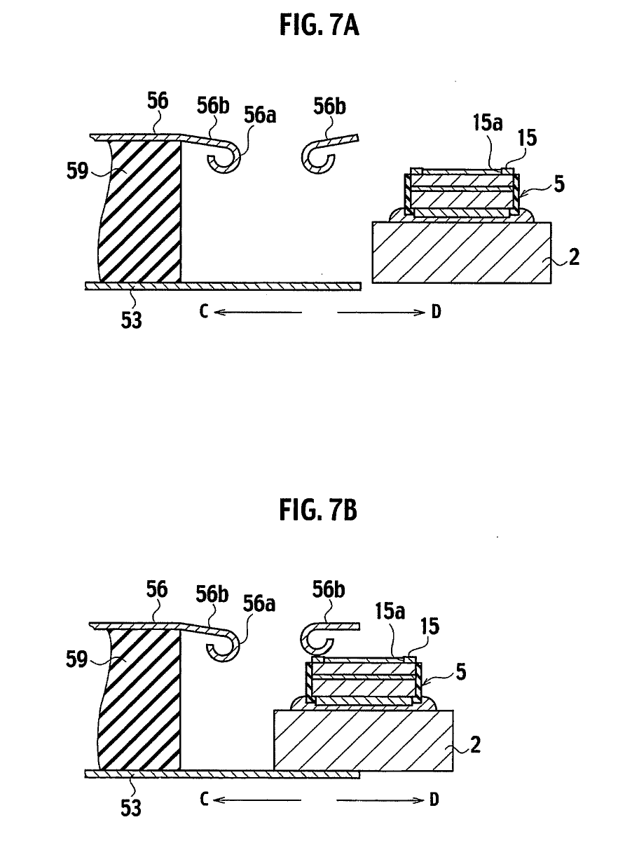

Next, a fourth embodiment will be explained with reference to FIGS. 6 and 7. The fourth embodiment is an embodiment in which partial modification is applied to the first embodiment.

FIG. 6 is a view showing a cross sectional structure of a semiconductor light-emitting device of the fourth embodiment according to the present invention. FIGS. 7A and 7B are views each showing an assembly process of the semiconductor light-emitting device of the fourth embodiment according to the present invention. It should be noted that same reference numerals are assigned to the elements, which are the same as those of the first embodiment, and thus, descriptions thereof will be omitted here.

As shown in FIG. 6, a semiconductor light-emitting device 1A includes a supporting substrate 2, a p-side lead-out electrode 53, a bonding layer 4, a semiconductor light-emitting element 5, an n-side lead-out electrode 56, a phosphor sheet 8, and a resin layer 59.

The p-side lead-out electrode 53 is electrically connected to the bottom surface of the supporting substrate 2. Thereby, the p-side lead-out electrode 53 is connected to a p-side electrode 11 of the semiconductor light-emitting element 5 through the supporting substrate 2 and the bonding layer 4.

The n-side lead-out electrode 56 is provided above the semiconductor light-emitting element 5 in a way that the n-side lead-out electrode 56 covers the supporting substrate 2. An opening portion 56a is formed at a position of the n-side lead-out electrode 56, the position corresponding to a light-emitting window 15a of an n-side electrode 15. Furthermore, an elastic portion 56b, which can be elastically deformed, is formed at a portion of the outer frame of the opening portion 56a. It should be noted that the p-side lead-out electrode 53 and the n-side lead-out electrode 56 are fixed with the resin layer 59 interposed therebetween while retaining a predetermined interval between the p-side lead-out electrode 53 and the n-side lead-out electrode 56.

Next, assembly processes of the semiconductor light-emitting device 1A will be explained with reference to FIGS. 7A and 7B. As shown in FIG. 7A, before the assembly, the elastic portion 56b of the n-side lead-out electrode 56 is tilted downward. In this state, the semiconductor light-emitting element 5 fixed on the supporting substrate 2 is inserted from the outer side in a direction indicated by an arrow D into a space between the p-side lead-out electrode 53 and the n-side lead-out electrode 56. The semiconductor light-emitting element 5 is inserted until an upper end portion of the semiconductor light-emitting element 5 in a direction indicated by an arrow C abuts on a side of the elastic portion 56b in the direction D. Then, as shown in FIG. 7B, the downwardly tilted shape of the elastic portion 56b in the direction D is elastically deformed into a substantially horizontal shape. When the semiconductor light-emitting element 5 is further inserted therebetween in the direction C, the elastic portion 56b in the direction C also changes to a substantially horizontal shape by being pressed up by an upper end portion of the semiconductor light-emitting element 5 in the direction C. Finally, when the semiconductor light-emitting element 5 is inserted until the supporting substrate 2 abuts on the resin layer 59, the assembly process ends, and thereby the semiconductor light-emitting device 1A is completed as shown in FIG. 6.

(Function and Effects)

As described above, the elastic portion 56b, which can be elastically deformed, is provided to the n-side lead-out electrode 56. Accordingly, the semiconductor light-emitting element 5 can be prevented from being damaged by excessive pressure to be applied thereto when connecting the n-side lead-out electrode 56 and the n-side electrode 15 to each other. In addition, the same effects as those of the first embodiment can be obtained.

### Fifth Embodiment

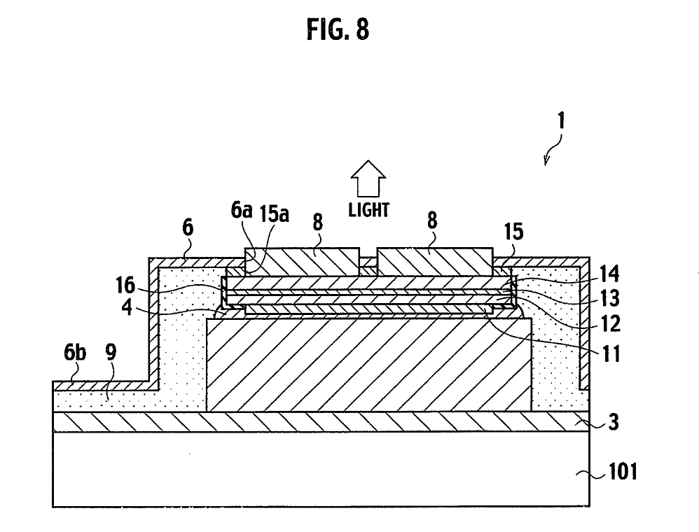

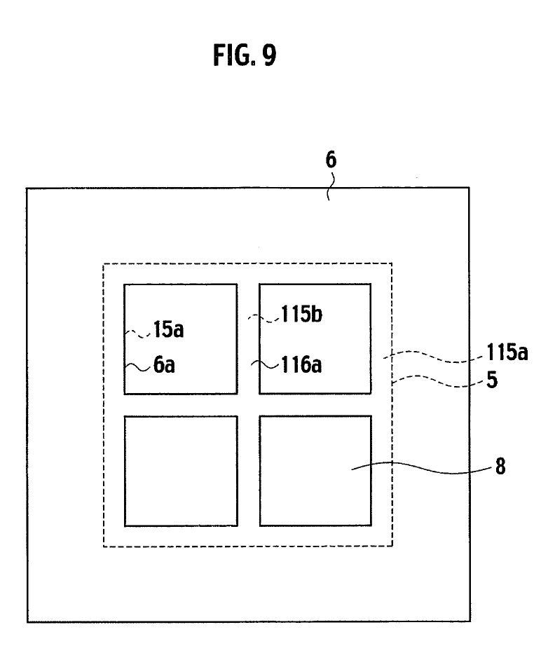

Hereinafter, descriptions of a fifth embodiment of the present invention will be provided with reference to FIGS. 8 and 9. It should be noted that descriptions of differences between the aforementioned first embodiment and the fifth embodiment are mainly provided below.

Specifically, in the case of the first embodiment, the n-side lead-out electrode 6 includes the opening portion 6a in which a single opening is formed. On the other hand, in the case of the fifth embodiment, an n-side lead-out electrode 6 includes an opening portion 6a in which multiple openings are formed.

(Structure of Semiconductor Light-Emitting Device)

Hereinafter, a structure of a semiconductor light-emitting device according to the fifth embodiment will be explained with reference to FIGS. 8 and 9. FIG. 8 is a view showing a cross sectional structure of the semiconductor light-emitting device of the fifth embodiment according to the present invention. FIG. 9 is a plan view of the semiconductor light-emitting device of the fifth embodiment according to the present invention.

As shown in FIGS. 8 and 9, the structure of a semiconductor light-emitting device 1 of the fifth embodiment is similar to the structure of the semiconductor light-emitting device 1 of the first embodiment. However, the shapes of the n-side lead-out electrode 6 and an n-side electrode 15 provided to the semiconductor light-emitting device 1 of the fifth embodiment are different from those in the case of the first embodiment.

Specifically, the n-side electrode 15 is provided to the top surface of a semiconductor light-emitting element 5. The n-side electrode 15 includes an outer frame 115a, and an inner frame 115b of grid shape, which is provided the inner side of the outer frame 115a. Moreover, the n-side lead-out electrode 6 includes an inner frame 116a of grid shape, which is provided along the inner frame 115b of the n-side electrode 15 in an opening portion 6a.

(Function and Effects)

As described above, in the case of the fifth embodiment, the n-side lead-out electrode 6 includes the inner frame 116a of grid shape in the opening portion 6a, and also includes multiple openings partitioned by the inner frame 116a. Accordingly, it is possible to pursue improvement in the heat radiation of the semiconductor light-emitting device 1 while controlling reduction in the amount of light emitted from the top surface of the semiconductor light-emitting element 5.

[Modified Examples]

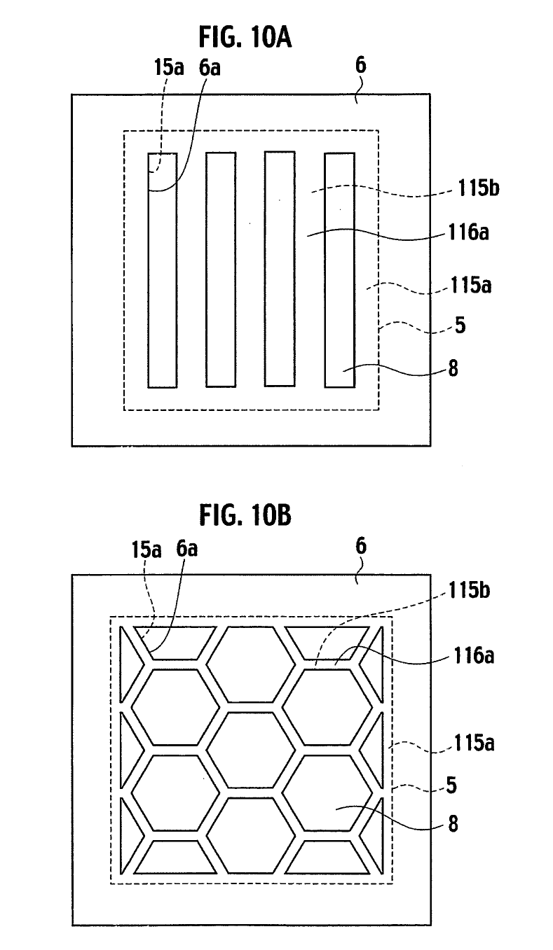

Hereinafter, modified examples of the fifth embodiment will be explained with reference to FIGS. 10A and 103. FIGS. 10A and 10B are plan views respectively showing modified examples of the semiconductor light-emitting device of the fifth embodiment according to the present invention.

As shown in FIG. 10A, the n-side electrode 15 includes an inner frame 115b of stripe shape provided to the inner side of the outer frame 115a, and the n-side lead-out electrode 6 may include an inner frame 116a of stripe shape being provided along the inner frame 115b of the n-side electrode 15 in the opening portion 6a.

Likewise, as shown in FIG. 10B, the n-side electrode 15 includes an inner frame 115b of mesh shape being provided to the inner side of the outer frame 115a, and the n-side lead-out electrode 6 may include an inner frame 116a of mesh shape being provided along the inner frame 115b of the n-side electrode 15 in the opening portion 6a.

[Other Embodiments]

Although the description of the present invention has been provided so far by use of the aforementioned embodiments, it is obvious to those skilled in the art that the present invention is not limited to the embodiments described in this specification. The present invention can be implemented as a modified embodiment without departing from the spirit and the scope of the invention defined by the description of the scope of the appended claims. Accordingly, the descriptions of this specification are provided for the purpose of explaining examples, and do not imply any limitation on the invention. Hereinafter, descriptions of modified embodiments will be provided, in which partial modification is applied to the aforementioned embodiments.

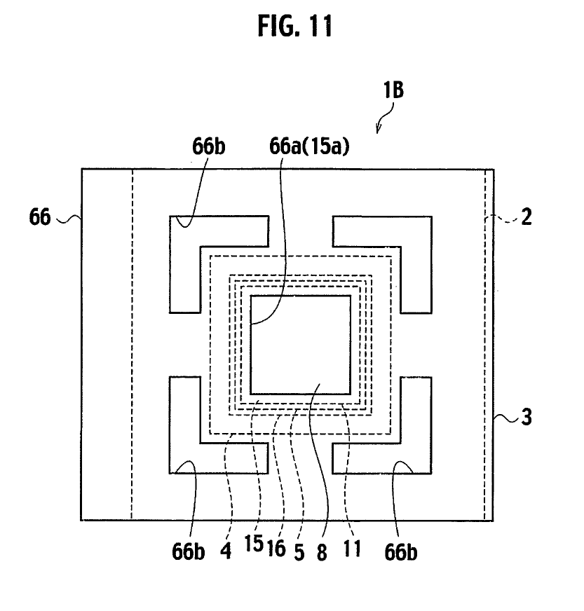

For example, although one opening portion 6a is provided to the n-side lead-out electrode 6 in the first embodiment, the present invention is not limited to this. Specifically, another opening portion may be provided outside the opening portion 6a. FIG. 11 is a plan view showing a semiconductor light-emitting device of the modified embodiment according to the present invention. As shown in FIG. 11, an opening portion 66a is formed in a position of an n-side lead-out electrode 66, the position corresponding to the top surface of the semiconductor light-emitting element 5, and also, auxiliary opening portions 66b are provided in four corners of the outer sides of the semiconductor light-emitting element 5.

By implementing such a structure, light emitted from the side surfaces of the semiconductor light-emitting element 5 can be emitted outside through the auxiliary opening portions 66b. This feature is particularly effective in a case where the semiconductor light-emitting element 5 is formed on a light transparent substrate, and a large amount of light emits from the side surfaces of the semiconductor light-emitting element 5. Incidentally, an n-side lead-out electrode including an auxiliary opening portion may be formed in the other embodiments described above in a similar manner to this modified embodiment.

Moreover, although the n-side electrode 15 is formed in a way that the n-side electrode 15 surrounds the four sides of the top surface of the semiconductor light-emitting element 5 in the aforementioned embodiments, the n-side electrode 15 may be formed along at least two of the four sides, not necessarily all of the four sides. Moreover, in a case where the top surface of the semiconductor light-emitting element is a polygonal shape having not less than four sides, an electrode may be formed along all of the sides thereof. Furthermore, an electrode of grid shape may be formed on the top surface of the semiconductor light-emitting element. It should be noted that it is preferred that the shape of an n-side lead-out electrode be changed so as to match the shape of an n-side electrode. For example, instead of the aforementioned opening portion 6a of the n-side lead-out electrode 6, an opening portion having a shape having only three sides may be formed while opening one of the four sides. Incidentally, an n-side electrode and an n-side lead-out electrode can be formed in the aforementioned other embodiments in a similar manner to the one described above.

Moreover, although the semiconductor light-emitting device 1 including only one semiconductor light-emitting element 5 is suggested in the first embodiment, the present invention may be applied to a semiconductor light-emitting device including multiple semiconductor light-emitting elements. For example, multiple semiconductor light-emitting elements may be arranged on a substrate in a matrix. Then, an n-side lead-out electrode, in which multiple openings are formed corresponding respectively to the semiconductor light-emitting elements, may be formed in a way that the electrode covers the top surfaces of all of the semiconductor light-emitting elements.

Furthermore, although the semiconductor light-emitting element 5 capable of emitting blue light or ultraviolet light is employed in the aforementioned embodiments, a semiconductor light-emitting element capable of emitting light of another color may be employed. Incidentally, in a case where a semiconductor light-emitting element capable of emitting light of another color is employed, the phosphor sheet 8 may be removed.

Furthermore, although the conductive supporting substrate 2 and conductive supporting substrate 22 are used in the aforementioned embodiments, an insulating supporting substrate may be employed.

Moreover, although the n-side lead-out electrode is configured of a metallic plate material, an n-side lead-out electrode made of a metallic thin film may be formed directly on a resin layer by patterning, metal deposition or etching. It should be noted that in a case where such a configuration is employed, it is preferable that the n-side lead-out electrode be configured of a metallic thin film having a larger cross sectional area than that of a commonly used wire.

Moreover, it is possible to apply the configurations of the aforementioned n-side electrode and the n-side lead-out electrode to the p-side electrode and the p-side lead-out electrode, respectively, in the case of forming a p-side electrode on a surface from which light of a semiconductor light-emitting element emits.

What is claimed is:

1. A semiconductor light-emitting device comprising:
a semiconductor light-emitting element including a light-emitting surface of polygonal shape, and an electrode formed on the light-emitting surface; and
a lead-out electrode connected to the electrode, wherein,
the electrode is formed along at least two sides of the light-emitting surface, and
the lead-out electrode is formed on the electrode, and includes an opening portion which opens toward an upper side of the light-emitting surface.

2. The semiconductor light-emitting device according to claim 1, wherein,
the semiconductor light-emitting element emits any one of a blue light or an ultraviolet light from the light-emitting surface, and
a phosphor is provided to an area of the light-emitting surface, on which area the electrode is not formed, the phosphor emitting a fluorescent light by absorbing the light emitted from the light-emitting surface as an excitation light.

3. The semiconductor light-emitting device according to claim 1, wherein,
the lead-out electrode includes an auxiliary opening portion which opens toward the upper side of the semiconductor light-emitting device, and
the auxiliary opening portion is provided to an outside of the opening portion.

4. The semiconductor light-emitting device according to claim 1, wherein,
the lead-out electrode includes an inner frame in the opening portion, and
the electrode is disposed along the inner frame, and disposed on the light-emitting surface.

5. The semiconductor light-emitting device according to claim 1, wherein,
a bottom surface of the lead-out electrode, side surfaces of the semiconductor light-emitting element and side surfaces of the electrode, are filled with an insulating material.

6. The semiconductor light-emitting device according to claim 1, wherein,
the semiconductor light-emitting element is provided on a substrate made of a non-light-transparent material.
